(19) United States
(12) Patent Application Publication
(10) Pub. No.: US 2026/0104595 A1
(43) Pub. Date: Apr. 16, 2026

(54) A Thin Disk Laser System

(71) Applicant: FYZIKALNI USTAV AV CR, V. V .I., Czech Republic (CZ)

(72) Inventors: Kohei Hashimoto, Dolni Brezany (CZ); Michal Chyla, Dolni Brezany (CZ); Martin SMRZ, Dolni Brezany (CZ)

(73) Assignee: FYZIKALNI USTAV AV CR, V. V .I., Czech Republic (CZ)

(21) Appl. No.: 19/114,467

(22) PCT Filed: Sep. 22, 2022
(86) PCT No.: PCT/CZ2022/050097

§ 371 Date: Mar. 24, 2025

(30) Foreign Application Priority Data
Sep. 22, 2021 (LU) 102858

(51) Int. Cl. G02B 27/09; G02B 19/00; G02B 27/12; H01S 3/06; H01S 3/0941

(52) U.S. Cl. CPC G02B 27/0927; G02B 19/0009; G02B 19/0052; G02B 27/0972; G02B 27/126; H01S 3/0604; H01S 3/0941

(57) ABSTRACT

A beam shaping optical system for direct pumping of thin disk laser head with laser diode module. The present invention relates to a laser system. More particularly, the present invention relates to a diode pumped laser system. Even more particularly, the present invention relates to a laser diode pumped thin disk laser, wherein the laser head is coupled to the laser diode-pumping source by a fiber cable.

### TECHNICAL FIELD

The present invention relates to a portable laser system. More particularly, the present invention relates to an inhomogeneously pumped thin disk laser system, preferably pumped by a stack of a laser diode. In a preferred embodiment, the present invention relates to a laser diode pumped thin disk laser, wherein a laser head comprising a thin amplifying disk is coupled to a laser diode-pumping source delivering inhomogeneous pump beam, wherein the system homogenizes the pump beam.

### STATE OF THE ART

The thin-disk laser is a diode-pumped high-power solid-state laser. The gain medium is a thin disk, wherein the thickness is considerably smaller than the diameter. This geometry allows efficient cooling of the whole surface of the disk and provides flat temperature profile through 1D-heat flow, which leads to low thermal lensing and nonlinear effects, like self-phase modulation (SPM) or self-focusing (SF). The small thickness of the disk typically leads to inefficient pump absorption when only a single or double pass is used. This problem is normally solved by using a multi-pass pump arrangement, which can be made compact when using a well-designed optical setup, typically containing a parabolic mirror and prism retroreflectors. Such arrangements easily allow arranging plurality of passes of the pump radiation through the disk without excessively stringent requirements on the pump beam quality.

The laser disk is separated from the diode-pumping source, wherein the pumping light is delivered to a laser head by an optical fiber. The laser head comprises said thin disk for receiving the pumping light and its absorption. A basic scheme is shown in FIG. 1 which shows a diode-pumping source 1 generating a pump beam, wherein the diode-pumping source 1 is coupled to a pumping chamber through an optical cable 2. The pump beam is directed to a collimating lens 3 and to the parabolic mirror 4 for beam reflection to a thin disk 5 for pump beam absorption. The thin disk 5 is connected to a heat sink 6. In the pumping chamber, a reflector 7 receiving and reflecting the pump beam back is provided. At the end of the final pass of the pump beam, the laser beam 8 is almost fully absorbed in a thin disk.

The optical fiber 2 has circular cross section. However, the pump spot shape on a thin disk after first reflection off the parabolic mirror 4 is elliptical and declined due to aberrations introduced by the parabolic mirror 4. The realistic elliptical pump spot shape 10 after reflection off the parabolic mirror is shown in FIG. 2, where is also shown the ideal circular shape 11 that would be obtained, if a spherical focusing lens was used instead of parabolic mirror 4. The proposed scale as shown in FIG. 2 does not show any limitation. This is a simple example of the embodiment which can be provided as it is shown in FIG. 3a. When the elliptical beam is propagated through the pumping chamber as shown in FIG. 3b, after multiple reflections, the superimposing of the elliptical declined beam results in a quasi-circular pump spot shape and the cross section shows significant decline and smeared edges of the pump spot as schematically shown in FIG. 3c.

DE 10 2017 108 936 A1 discloses a laser system for delivering a homogeneous beam into a thin disk, wherein a pump source is a stack of laser diodes providing an inhomogeneous pump beam. The laser system according to the above-mentioned solution is capable to deliver a homogenized beam to thin disk, wherein the pump beam is amplified. The system, however, comprises a plurality of microlenses which are not easily manufactured and furthermore the microlenses require further requirements on alignment.

It is a general technical wish to provide a top hat beam spot, preferably having circular spot, having homogenous intensity to be delivered into a laser head comprising the thin disk so that the amplification of the pump beam is efficient and homogenous as well. Therefore, the object of the present invention is to provide a beam-shaping system compensating inhomogeneous intensity thereof, preferably circular beam profile. At the same time, the present invention should overcome the problem with the optical beam alignment, in particular with respect to the optical elements such as lenses or prisms, and requirements of the on the precision of all optical elements contained in the solution shall be as less as possible.

### SUMMARY OF THE INVENTION

The above-mentioned technical problems are solved by the present invention as claimed in independent claims appended in this application.

In the first aspect, the present invention relates to a laser system capable to shape and homogenized an optical pump beam in terms of intensity. The system is providing a homogenized pump optical beam to laser head, in particular to a thin disk amplifying the pump beam. The source of the pumped optical beam is an inhomogeneous optical beam, such as the beam of rectangular or squared shape profile, for example the pump beam from a stack of laser diode, wherein the system according to the present invention is capable to deliver a homogenous beam spot to a thin disk and delivering a circular spot as the laser output. The system is defined by claim 1.

The system comprises:
a source for generating an inhomogeneous optical beam in term of optical intensity, wherein the inhomogeneous optical beam can be, not exclusively, a non-circularly shaped profile, such as a rectangular or square beam shape from a stack of a laser diode;
a single piece of a beam-dividing and rotating prism receiving the inhomogeneous optical beam, wherein the beam-dividing and rotating prism has a first part providing a longer optical path and a second part providing shorter optical path, and wherein
   the beam-dividing and rotating prism is configured to divide the inhomogeneous optical beam into two parts, wherein the first part is propagating through the longer optical path and the second part is propagating through the shorter optical path, and wherein
   the beam-dividing and rotating prism is configured to rotate each parts by the same direction and by the same angle;
a focusing means receiving both parts of the beam from the beam-dividing and rotating prism; and focusing thereof into a homogenizer; thereby providing a homogenized optical pump beam; and
a laser head receiving the homogenized optical beam from the homogenizer, wherein the laser head comprises a thin disk, and wherein the homogenized optical beam is directed onto the thin disk.

The combination of the beam-dividing and rotating prisms and the optical beam homogenizer, provides a homogenized optical beam spot, which is delivered on the thin disk comprised in the laser head. By repeating rotation and superimposing multiple polygonal spots, preferably near circular pump spot shape can be obtained on a thin disk. In some embodiment, the beam-dividing and rotating prism can reduce aspect ratio of the optical beam, suitable as a pump beam for a laser beam, for increased coupling efficiency into the homogenizer. Furthermore, the present invention is capable to be manufactured as a portable system, which can be handled by hands. Furthermore, due to a single piece of a beam-dividing prism, a technical problem to alignment and precision on microlenses is overcome. Furthermore, a single piece of beam dividing and rotating prism overcomes the problem with a beam alignment, for example, involved in a solution that need a plurality of prisms which are positioned on different places on an optical table.

The source generating an inhomogeneous optical beam suitable for pumping the beam into a homogenizer can be a plurality of laser diode stored in a diode stack, a plurality of diode stacks, a plurality of diode module or a plurality of a further laser beam. The optical beam is inhomogeneous in intensity but spatially, it can be collimated, between the source generating optical pump beam and beam dividing and rotating prism receiving this optical beam, in some embodiment with vertical divergence <1° and horizontal divergence <5°. In a preferred embodiment, the beam can be inhomogeneous in intensity but spatially collimated between the source generating inhomogeneous optical pump beam, such as a plurality of laser diode arranged into a circle or square or rectangle, and focusing means receiving the rotated pump beam and focusing thereof into a polygonal or elliptical homogenizer, with vertical divergence <1.8° and horizontal divergence <3.6°. Preferred embodiments of the source generating an inhomogeneous optical beam are defined by claim 2. The most preferred embodiment is the source generating an inhomogeneous optical beam comprising a plurality of elliptical or circular beams, such as laser diodes, forming together a rectangular envelope, or a square envelope, due to their arrangement in a stack.

The beam-dividing and rotating prism is a single piece of prism having two parts. The first part provides a longer optical path. The second part provides a shorter optical path. Both parts are made from the same material such as transparent glass. The inhomogeneous optical beam, when received by the front of the beam-dividing and rotating prism, is divided into two parts. The first half propagates through the longer optical path. The second half propagates through the shorter optical path. Both parts are then reflected twice by right angle so that first part and the second part have the shape and intensity distribution inverted with respect to each other. At the back of the beam-dividing and rotating prism, the beam is still inhomogeneous, however, doubled and one half is flipped, resp. inverted, with respect to the other part.

In a preferred embodiment, the focusing means are two cylindrical lenses, wherein the second lens direction is orthogonal to the first lens, wherein the focal lengths are chosen to fit within the numerical aperture of the homogenizer, based on the size of the beam emitted from the beam-dividing and rotating prism.

The homogenizer is an optical transparent laser rod, which is provided with a high reflective coating on its surface, and which is capable to multiply reflect the inhomogenous optical pump beam so that, at the end of the laser rod, the beam is fully homogenized. Such a homogenizer is known from the state-of-the-art, for example from the document cited in the prior art section. In a preferred embodiment, the homogenizer is polygonal, even more preferably an octagonal homogenizer with asymmetric geometry, where vertical and horizontal cross sections dimensions are configured to compensate difference in magnification of vertical and horizontal planes introduced by aberrations of a parabolic mirror.

In a further preferred embodiment, the system further comprising an anamorphic prism pair disposed between a plurality of laser diode stack, preferably having large rectangular shaped emitting area and a beam-dividing and rotating prisms. The anamorphic prism pair allows decreasing the size of the inhomogeneous optical beam and convert the inhomogeneous optical beam to near square shape and to fit the beam on beam-dividing and rotating prisms.

In a further preferred embodiment, the system comprising plurality sources of inhomogeneous optical beam. At least two sources of inhomogeneous optical beam provide higher power of the pumping, therefore higher power of pumping power of the laser beam emitted from the laser head.

In a further preferred embodiment, the system further comprises a bar mirror array positioned between the plurality of laser diode stacks and the beam-dividing and rotating prism.

In a more preferred embodiment, the system further comprising a polarizer deposited between the plurality of laser stacks and a beam-dividing and rotating prisms. In a more preferred embodiment, a half-wave plate is inserted in front of the laser diode stack. This arrangement allows combining two polarized beams into one, more powerful beam.

In a further preferred embodiment, the system further comprising a bar mirror array deposited between plurality of laser diode stacks and a beam-dividing and rotating prisms. This arrangement allows combining beams into one, more powerful beam by reflecting beams emitting from bars of one of the laser diode stack into direction of emission of the second laser diode stack.

In a further preferred embodiment, the system further comprising a laser diode stack module with fast and slow axis collimators providing fast axis divergence <0.5° and slow axis divergence <4°.

An alternative embodiment of the present invention is a laser system homogenizing an optical pump beam from an inhomogeneous pump source and delivering the homogenous pump beam to a laser head comprising a thin disk active medium amplifying the homogenized pump beam.

The system comprises:
a plurality of source generating an inhomogeneous optical beam in term of optical intensity;
means for dividing and collimating beam comprising:
   a fast axis collimator receiving inhomogeneous optical beam from the plurality of the source;
   a beam twister receiving the optical beam from the fast axis collimator; and
   a slow axis collimator receiving the inhomogeneous optical beam from the beam twister; and
a focusing means receiving the beam from the means for dividing and collimating beam; and focusing thereof into a homogenizer; thereby providing a homogenized optical pump beam; and
a laser head receiving the homogenized optical beam from the homogenizer, wherein the laser head comprises a thin disk, and wherein the homogenized optical beam is directed onto the thin disk.

In another embodiment, the octagonal homogenizer has an octagonal front face dimensions: 1.3 mm width, 1.6 mm height, 0.4 mm chamfer at 45 degrees; for pump power up to 1 KW of average power.

In another embodiment, the octagonal homogenizer has the length in range 80-100 mm.

In yet another embodiment, the octagonal homogenizer has the length in range 100-120 mm.

In yet another embodiment, the octagonal homogenizer has the length in range 120-150 mm.

The above-mentioned embodiments can be unlimitedly used in all filed of industrial application, in particular in cutting, etching, annealing, welding, drilling, soldering, high-temperature plasma creation, particle acceleration, or as a scientific instrument.

### BRIEF DESCRIPTION OF DRAWINGS

FIG. 1 represents a schematic drawing of a diode-pumped solid-state laser comprising a thin disk situated in a pumping chamber according to state of the art.

FIG. 2 schematically represents a difference between an optimal circular pump spot from a lens-based system and elliptical beam as a result of reflection from a parabolic mirror according to the state of the art.

FIGS. 3a-3d represent simulation results based on laser system according to the state of the art showing beam propagation from end of the pump fiber tip-previous technique (a), through the first reflection from the parabolic mirror (b) to the superimposed position of all reflections from the parabolic mirror (c), where (d) shows the cross-section of the final pump spot structure.

FIG. 4 represents simulation result based on a laser system according to the present invention beam propagation from end of the homogenizer—this invention (a), through the first reflection from the parabolic mirror (b) to the superimposed position of all reflections from the parabolic mirror (c), where (d) shows the cross-section of the final pump spot structure.

FIG. 5 schematically represents an embodiment of the present invention.

FIG. 6 represents a detailed view on beam dividing prism according to one embodiment of the present invention.

FIG. 7 represents simulations of a pump beam cross section intensities evolution in a homogenizer according to a one embodiment of the present invention.

FIG. 8 represents schematically represents a homogenizer according to the present invention, wherein a pump beam is directed to a pumping chamber. The FIG. 5 is accompanied with the representation of beam profiles on the end of the homogenizer and on the thin disk.

FIG. 9 represents simulation of a pump beam profile after transmitting through a beam-dividing and rotating prism, homogenizer and pumping chamber with multiple reflections on the thin disk according to a one embodiment of the present invention.

FIG. 10a and FIG. 10b represent cross-sections of the simulated final pump spot size as the output from the embodiment from FIG. 5.

FIG. 11 schematically represents an improved embodiment further comprising an anamorphic prism pair according to another embodiment of the present invention.

FIG. 12 schematically represents a cross section of the second embodiment according to FIG. 11, wherein a pump beam path is schematically shown.

FIG. 13 represents a further improved embodiment directed to power scaling arrangement with bar mirror array and two diode stacks providing 400 W laser beam according to a third embodiment of the present invention.

FIG. 14 represents a top view on the embodiment shown in FIG. 13 having two diode stacks and propagation of the pumping beam.

FIG. 15 represents a further embodiment directed to power scaling arrangement with thin-film polarizer and a half-wave plate and two diode stacks providing 400 W laser beam according to the embodiment FIG. 14.

FIG. 16 represents the top-view on the embodiment in FIG. 15.

FIG. 17 represents an alternative embodiment for a beam homogenization.

FIG. 18 represents a detailed view on the alternative embodiment from FIG. 17. In particular, FIG. 18 represents an embodiment according to the present invention comprising a laser diode with fast axis collimator (FAC), beam twister (BT) and slow axis collimator (SAC).

FIG. 19 represents an intensity beam distribution from four diode bars in a laser diode stack with indicated rectangular envelope of the beam.

FIG. 20 represents a schematic drawing of the octagonal homogenizer used in the present invention.

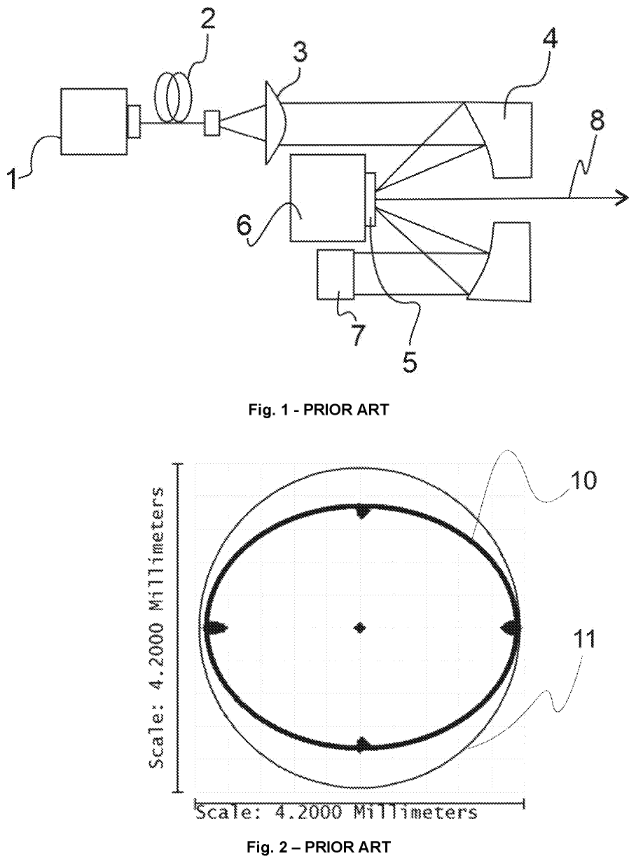

### DETAILED DESCRIPTION

The following description is presented to provide an exemplary embodiment of the system capable to provide homogenized and shaped optical beam. Said optical beam can be used as a pump beam directed to a laser head emitting a laser beam, in particular a compact and robust laser head with direct laser diode pumping. The pumping optical beam is emitted by plurality of optical sources, such as laser diode stacks, resulting in inhomogeneous optical beam with the term of optical intensity. In case of laser diode stack, the final envelope can be rectangular or squared depending on the shape of laser diode stack. It is a general desire to deliver a homogenous beam, e.g. top-hat beam, to the laser head. The main advantage of the present invention is a portability of them laser system and easy to install system without any further needs to align special optical elements within the system.

In a first example, the inventors propose direct pumping of thin disk laser head with laser diode stack, which brings numerous advantages. Firstly, the robustness and reliability will significantly improve due to the absence of the optical fiber, which is usually used to deliver the pump light from a fiber coupled laser diode into the thin-disk laser head. Such optical fibers require careful handling, especially during installation that in case of industrial thin disk laser is done partially at the customers' site, where the fiber coming out of the laser is connected to the laser cabinet with fiber coupled laser diodes (both modules need to be disconnected for transport and part of installation). Because of this design, there is always the risk of damaging the tip of the high-power fiber upon connection.

Secondly, the cost of a thin disk laser can be significantly reduced, thanks to the absence of optical fiber and the possibility to directly use cheap laser diodes stacks instead of price and complex fiber coupled laser diodes modules.

Another important improvement is a simpler service of the beam pumping source. Since the diode and the collimation optics are separated, it would be possible to only replace the faulty laser diode stack. Whereas, current fiber coupled laser diodes modules usually require service repair of the entire module and in case of the laser diode stack exchange, the fiber coupling optics need to be realigned, making the whole repair more complex.

Moreover, this solution provides an additional benefit due to the possibility to use other pumping wavelengths in case of different gain materials, simply by choosing a proper laser diode stack available from a wide range of pumping wavelengths. Besides, due to the absence of the optical fiber, more pumping wavelengths could be considered, since this component is no longer a limitation, which is important for 2 μm range lasers.

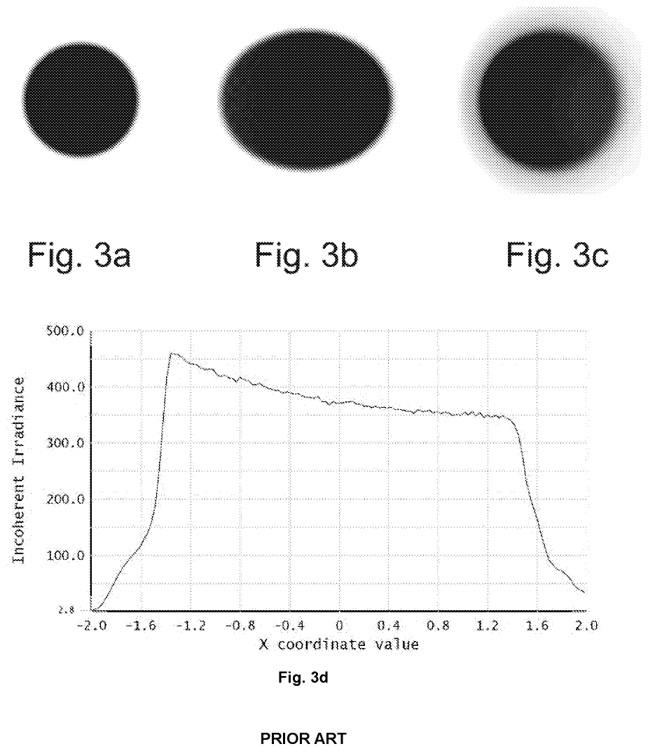

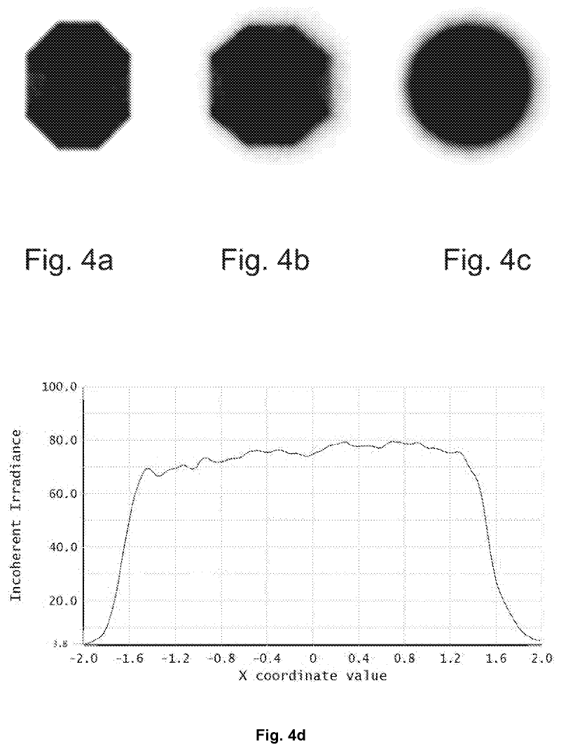

In case of standard, fiber-pumped laser heads the pump beam coming from the fiber is circular (FIG. 3a) and after reflection from the parabolic mirror in a laser head, it is deformed due to aberrations of the parabolic mirror and spot on the thin disk becomes elliptical, declined in cross-section and moves off center (FIG. 3b). When this elliptical beam is propagated through the pumping chamber, after multiple reflections, the superimposing of the elliptical declined beam results in a quasi-circular pump spot shape (FIG. 3c) and the cross section shows significant decline and smeared edges of the pump spot as it is shown in simulation results in FIG. 3d. In this invention, the inventors compensate the aberrations of the parabolic mirror and the beam at the output of the homogenizer has elliptical-type shape (FIG. 4a) which after reflection from the parabolic mirror becomes symmetrical on the thin disk (FIG. 4b). When this beam is propagated through the pumping chamber, after multiple reflections, the superimposing of the beam results in a circular pump spot shape (FIG. 4c) and the cross section shows significant improvement of the pump spot shape in comparison to the fiber-pumped solution (FIG. 4d).

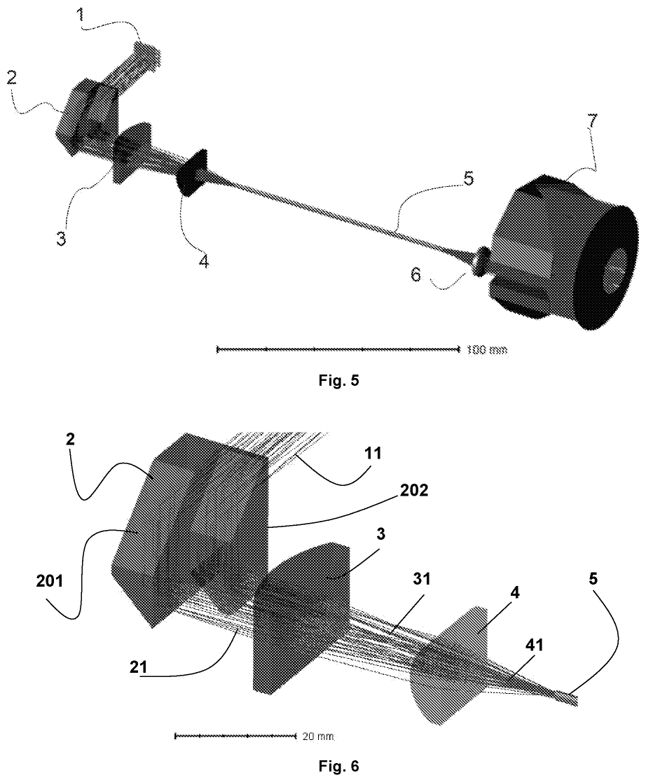

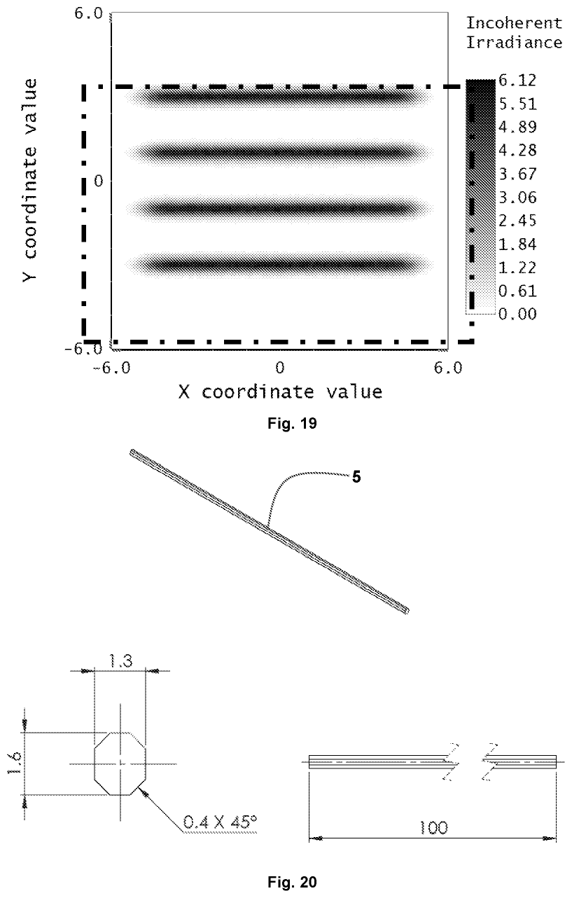

FIG. 5 represents a detailed view of the embodiment of the present invention. In particular FIG. 5 shows a source 1 generating an inhomogeneous optical beam 11. The inhomogeneous optical beam 11 has different intensity profile, for example as shown in FIG. 19. Such the intensity distribution can be provided by a plurality of diodes arrange in a laser diode stack 1 of rectangular shape. FIG. 5 further shows a single piece of beam dividing and rotating prism 2 which is receiving the inhomogeneous optical beam 11 from the source 1, in particular a laser diode stack 1. The source 1 of inhomogeneous beam 11 can comprise a laser diode stack with 4 bars (19 emitters per bar) delivering 200 W of average power at 940 nm wavelength. Output beam is collimated with fast and slow axis collimators. Afterwards, the beam is divided in half, rotated by 90 degrees and focused into octagonal homogenizing rod by set of two cylindrical lenses, as shown in FIG. 5. The beam dividing and rotating prism 2 is constructed so that, it divides the beam 11 into two parts 201, which the first part is propagating through a longer optical path and the second part 202 is propagating through a shorter path. The prism 2 is configured to rotate each part by the same direction and by the same angle. However due to the difference optical paths, the resulted beam 21 in a first part 201 is inversed with respect to the second part 202 of the beam 21. So, the beam 21 is doubled with respect to the inhomogeneous beam 11. FIG. 5 shows focusing means 3 in particular, two cylindrical lenses 3 and 4, where in the second lens 4 direction is orthogonal to the first lens 3, and wherein the focal lengths are chosen to fit within the numerical aperture of the homogenizer based on the size of the beam emitted from the beam dividing and rotating prism 2. The FIG. 5 further shows a homogenizer 5 which can be the homogenizer according to the state-of-the-art as disclosed in the cited document above. The optical beam coming from the homogenizer 5 is completely homogenized and ready to be focused to the laser head comprising a thin disc for the pump beam amplification. The focusing to the laser head 7 can be provided by state-of-the-art focusing means 6.

FIG. 6 is a detailed view on a beam dividing and rotating prism 2 receiving the inhomogeneous pump optical beam 11. FIG. 6 discloses a constructional view on the beam dividing rotating prism 2 showing in particularly two parts 201 and 202 providing a short and a long optical paths, wherein the optical paths are represented by lines. The beam dividing and rotating prism has two parts. The beam dividing and rotating prism is manufactured from a single piece of material, such as crystal or glass. The method of manufacturing can be manufacturing the parts separately and bounded together after. The first part provides a longer optical path, therefore it corresponds to the slow axis. The second part provides shorter optical path, compared to the first part of the beam-dividing and rotating prism. As it can be seen from this figure the beam 21 is further propagated through the focusing means 3, a pair of cylindrical lenses 3 and 4 and then, the beam 32, resp. 41 propagate to the homogenizer 5.

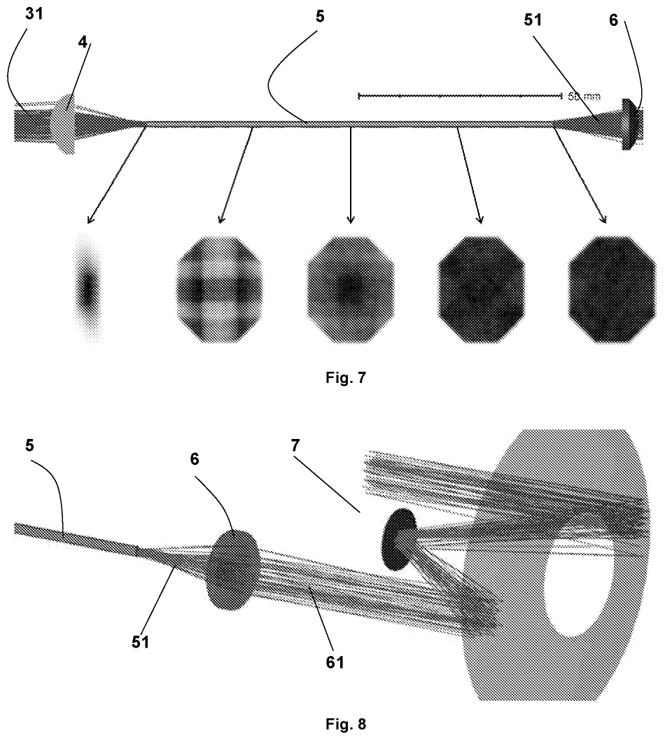

A circular and homogeneous pump spot structure obtained with this invention is shown in simulation results in FIG. 7. This high-quality pump spot shape is of important for the performance of high-power thin disk lasers operating in single-mode (TEM00) regime. FIG. 7 in particular represents the process of beam homogenizing by multiple reflection through the beam homogenizer 5.

FIG. 8 discloses a pump beam 51 output from a homogenizer 5 received by earth further means 6 of focusing which transmit the focused homogenized pump beam 61 to a laser head 7. The laser head 7 may comprises a plurality of mirrors which transmit the beam 61 to a thin disk. The thin disc and leaser head 7 and the process of pump beam amplification is known from the state-of-the-art.

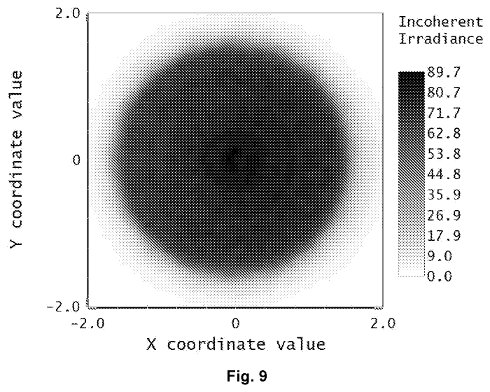

FIG. 9 represents the simulation result of the amplified homogeneous beam, which can be obtained from the system according to the present invention.

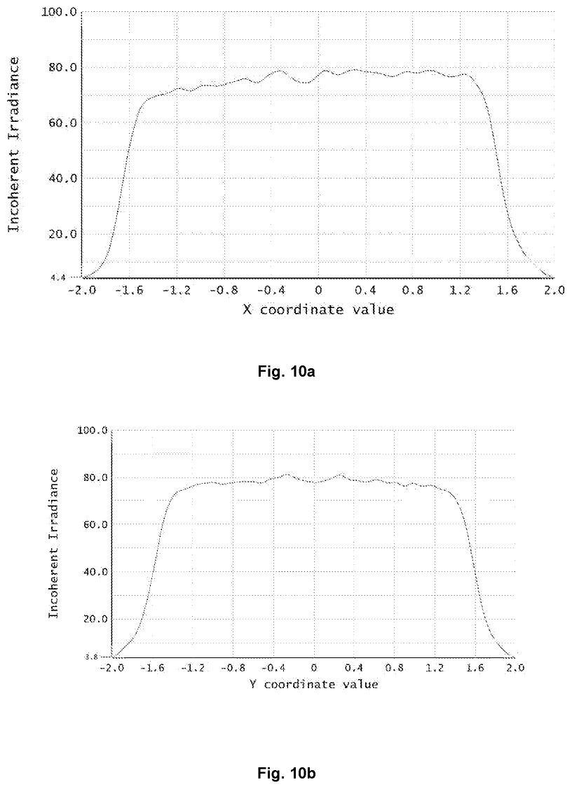

FIGS. 10a and 10b are the cross sections of the beam spot from the FIG. 9.

FIG. 11 discloses a pair of anamorphic prism 8 positioned between the beam dividing and rotating prism 2 and a laser stack 1.

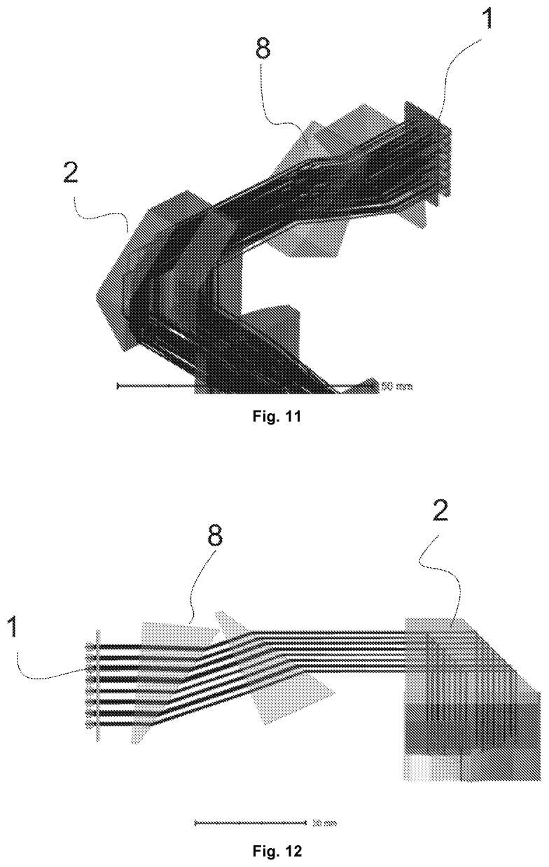

FIG. 12 is a top view on the embodiment shown in FIG. 11.

In order to increase the pumping power of this invention, there are three approaches that are incorporated into further embodiments of this invention. In a particular embodiment a laser diode stack with large number of diode bars can be used. Since the emitting area of the laser diode increases, an anamorphic prism pair 8 can be used to decrease the beam size so it fits onto the beam-dividing and rotating prism, which is shown in FIGS. 11 and 12.

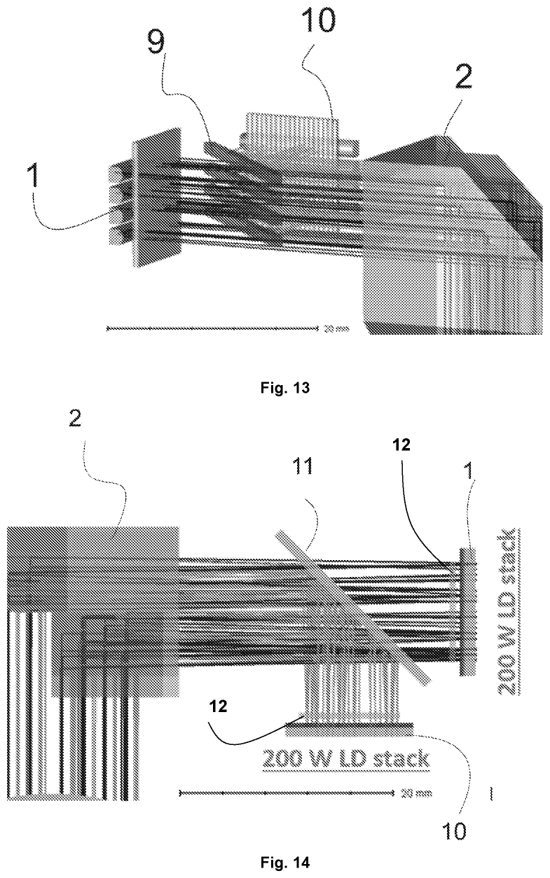

Another power upscaling method is beam combining of two (or more) laser diode stacks with the use of bar mirror array 11 to deflect the beam of the second (or more) diode stack into same direction, as shown in FIGS. 13 and 14.

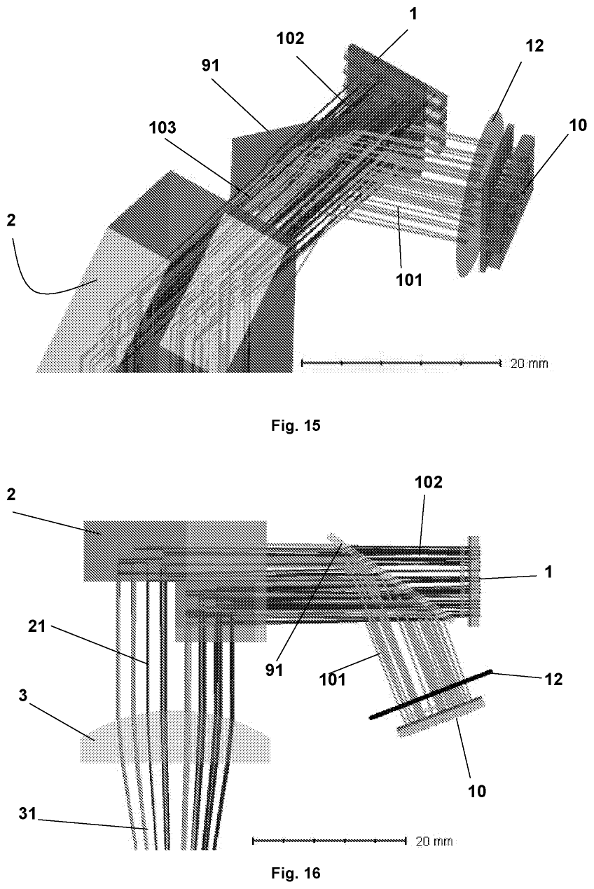

It is also possible to combine multiple beams from two (or more) diode stacks with the use of thin-film polarizer 12 and half-wave plate 91, where beam coming from the second (or more) diode stacks is combined into the beam coming from the first diode stack by change of polarization, as shown in FIGS. 15 and 16. The inhogoneous beams 102 and 101 are combined together.

By using the above mentioned power upscaling methods, pumping power of kW-level can be obtained.

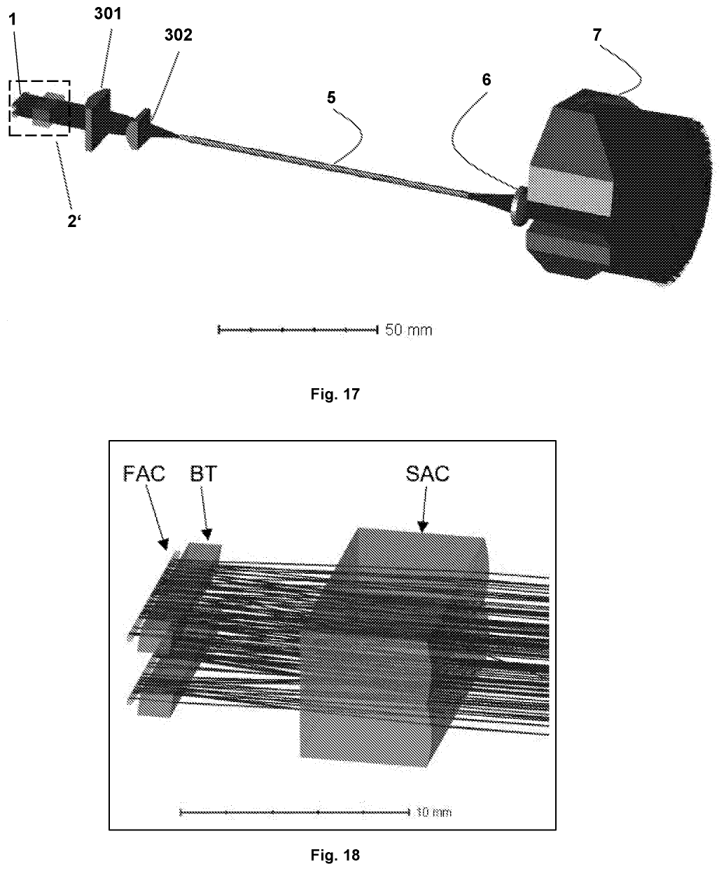

An alternative embodiment of the invention is shown in FIGS. 17 and 18. A laser system homogenizing an optical pump beam from an inhomogeneous pump source 1 and delivering the homogenous pump beam to a laser head 7 comprising a thin disk active medium amplifying the homogenized pump beam, wherein the system comprises: a plurality of source 1 generating an inhomogeneous optical beam in term of optical intensity; means 2′ for dividing and collimating beam comprising: a fast axis collimator FAC receiving inhomogeneous optical beam 11 from the plurality of the source 1; a beam twister receiving the optical beam from the fast axis collimator FAC; and a slow axis collimator SAC receiving the inhomogeneous optical beam 11 from the beam twister; and a focusing means 301 and 302 receiving the beam from the means 2′ for dividing and collimating beam; and focusing thereof into a homogenizer 5; thereby providing a homogenized optical pump beam 51; and a laser head 7 receiving the homogenized optical beam 51 from the homogenizer 5, wherein the laser head 7 comprises a thin disk, and wherein the homogenized optical beam 51 is directed onto the thin disk.

FIG. 20 represents a preferred embodiment of the homogenizer with its sizes.

Reference sign list

| | |
|---|---|
| 1 | Laser diode stack |
| 2 | Beam-dividing and rotating prism |
| 3 | 1^{st} lens |
| 4 | 2^{nd} lens |
| 5 | homogenizer |
| 6 | Focusing means |
| 7 | Leaser head |
| 8 | Anamorphic prism pair |
| 9 | Bar mirror array |
| 10 | Second source of inhomogeneous beam - |
| | second diode stack |
| 11 | Thin film polarizer |
| 12 | Half-wave plate |
| FAC | fast axis collimator |
| BT | beam twister |
| SAC | slow axis collimator |

1. A laser system homogenizing an optical pump beam (11) from an inhomogeneous pump source (1) and delivering the homogenous pump beam (61) to a laser head (7) comprising a thin disk active medium amplifying the homogenized pump beam (61), wherein the system comprises:
a source (1) generating an inhomogeneous optical beam (11) in term of optical intensity;
a single piece of a beam-dividing and rotating prism (2) receiving the inhomogeneous optical beam (11), wherein the beam-dividing and rotating prism has a first part (201) providing longer optical path and a second part (202) providing shorter optical path, and wherein
the beam-dividing and rotating prism (2) is configured to divide the inhomogeneous optical beam (11) into two parts, wherein the first part is propagating through the longer optical path and the second part is propagating through the shorter optical path, and wherein
the beam-dividing and rotating prism (2) is configured to rotate each parts by the same direction and by the same angle;
a focusing means (3 and 4) receiving both parts (21 and 31) of the beam from the beam-dividing and rotating prism (2); and focusing thereof into a homogenizer (5); thereby providing a homogenized optical pump beam (51); and
a laser head (7) receiving the homogenized optical beam (51) from the homogenizer (5), wherein the laser head (7) comprises a thin disk, and wherein the homogenized optical beam (51) is directed onto the thin disk.

2. The system according to claim 1, wherein the source (1) generating an inhomogeneous optical beam (11) is
a plurality of laser diode arranged in a stack of square and/or rectangular and/or circular shape; and/or
a plurality of laser diode stack (1 and 10) arranged in a space so that the inhomogeneous optical pump beam (11) is delivered to the beam-dividing and rotating prism (2); and/or
a plurality of laser bar; and/or
a plurality of laser emitter.

3. The system according to anyone of the preceding claims, wherein the homogenizer (5) is a polygonal homogenizer, preferably an octagonal homogenizer with asymmetric geometry, wherein vertical and horizontal cross sections dimensions are configured to compensate difference in magnification of vertical and horizontal planes introduced by aberrations of a parabolic mirror.

4. The system according to anyone of the preceding claims, wherein the focusing means (3 and 4) are two cylindrical lenses, wherein the second lens (4) direction is orthogonal to the first lens (3), and wherein the focal lengths are chosen to fit within the numerical aperture of the homogenizer (5), based on the size of the beam (21) emitted from the beam-dividing and rotating prism (2).

5. The system according to anyone of the claims 2 to 4 further comprising an anamorphic prism pair (8) positioned between the plurality of laser diode stack (1 and 10) and the beam-dividing and rotating prism (2).

6. The system according to anyone of the claims 2 to 4 further comprising a bar mirror array (9) positioned between the plurality of laser diode stacks (1 and 10) and the beam-dividing and rotating prism (2).

7. The system according to anyone of the claims 2 to 4 further comprising a polarizer (11) positioned between the plurality of laser diode stacks (1 and 10) and the beam-dividing and rotating prism (2).

8. The system according to claim 7 further comprising a half-wave plate (12) positioned between the plurality laser diode stack (1 and 10) and the polarizer (11).

9. The system according to anyone of the claim 7 or 8 further comprising a further bar mirror array (9) deposited between the plurality of laser diode stacks (1 and 10) and the beam-dividing and rotating prisms (2).

10. A laser system homogenizing an optical pump beam (11) from an inhomogeneous pump source (1) and delivering the homogenous pump beam (61) to a laser head (7) comprising a thin disk active medium amplifying the homogenized pump beam (61), wherein the system comprises:
a plurality of source (1) generating an inhomogeneous optical beam (11) in term of optical intensity;
means (2′) for dividing and collimating beam comprising:
a fast axis collimator (FAC) receiving inhomogeneous optical beam (11) from the plurality of the source (1);
a beam twister receiving the optical beam from the fast axis collimator (FAC); and
a slow axis collimator (SAC) receiving the inhomogeneous optical beam (11) from the beam twister; and
a focusing means (301 and 302) receiving the beam from the means (2′) for dividing and collimating beam; and focusing thereof into a homogenizer (5); thereby providing a homogenized optical pump beam (51); and
a laser head (7) receiving the homogenized optical beam (51) from the homogenizer (5), wherein the laser head (7) comprises a thin disk, and wherein the homogenized optical beam (51) is directed onto the thin disk.
